(19) United States
(12) Patent Application Publication
(10) Pub. No.: US 2011/0235963 A1
(43) Pub. Date: Sep. 29, 2011

(54) FIBER-COUPLED OPTOELECTRONIC DEVICE MOUNTED ON A CIRCUIT BOARD

(75) Inventor: Albert M. Benzoni, South Pasadena, CA (US)

(73) Assignee: HOYA CORPORATION USA, Santa Clara, CA (US)

(21) Appl. No.: 12/889,360

(22) Filed: Sep. 23, 2010

Related U.S. Application Data
(60) Provisional application No. 61/245,152, filed on Sep. 23, 2009.
(60) Provisional application No. 61/380,234, filed on Sep. 5, 2010.

(51) Int. Cl. G02B 6/12; H05K 3/00

(52) U.S. Cl. 385/14; 29/829

(57) ABSTRACT

An optical apparatus comprises: an optical fiber, an optoelectronic device on a substrate, a circuit board, and an electrical connection therebetween. A substrate groove positions the fiber for optical coupling with the device. The substrate is mounted on the circuit board; a proximal fiber segment is secured in the substrate groove; a distal fiber segment is secured to the circuit board. The circuit board includes vias providing electrical connections between contacts on its top and bottom surfaces. A method comprises: mounting on the circuit board the substrate and optoelectronic device; establishing the electrical connection; securing proximal and distal fiber segments to the substrate groove and circuit board, respectively. Multiple substrates can be secured to a single piece of circuit board material, which can be divided into individual circuit boards after establishing electrical connections and securing optical fibers to the corresponding substrates and circuit board material.

### BENEFIT CLAIMS TO RELATED APPLICATIONS

This application claims benefit of U.S. provisional App. No. 61/380,234 filed Sep. 5, 2010 and U.S. provisional App. No. 61/245,152 filed Sep. 23, 2009, both of said provisional applications being hereby incorporated by reference as if fully set forth herein.

### BACKGROUND

The field of the present invention relates to fiber-coupled optoelectronic devices mounted on circuit boards, or arrays of such devices.

This application discloses subject matter that may be related to subject matter disclosed in: U.S. provisional App. No. 60/778,777 filed Mar. 3, 2006; U.S. provisional App. No. 60/821,181 filed Aug. 2, 2006; and U.S. non-provisional application Ser. No. 11/681,352 filed Mar. 2, 2007 (now U.S. Pat. No. 7,543,993 issued Jun. 9, 2009). Each of said provisional applications, non-provisional application, and patent are hereby incorporated by reference as if fully set forth herein.

Packaging an optical component for ready coupling to an optical fiber is a costly and time consuming portion of the manufacturing process for optoelectronic devices for telecommunications. Connectors are available for enabling rapid connection between optical fibers, an end of each fiber being provided with one of a pair of mating connectors. In order to provide a packaged optoelectronic device with such a connector, it is often the case that a short segment of optical fiber is employed within the package, with one end optically coupled to the device and the other end terminating in the connector and available for coupling to another optical fiber with a mating connector. Alternatively, a short segment of optical fiber is employed within the package, with one end optical coupled to the device and the other end left free for subsequent splicing with another optical fiber.

In many typical applications, the optoelectronic device is coupled to electronic circuitry for use. It may be desirable in such circumstances to mount the fiber-coupled optoelectronic device directly on a circuit board for facilitating coupling between the device and the circuitry. It may be desirable to increase the density of multiple such fiber-coupled optoelectronic devices mounted together in a single apparatus or on a common system circuit board (e.g., to increase the lineal density of multiple devices mounted in a row). It may be desirable to arrange the mounting of the fiber-coupled optoelectronic device so as to reduce potential damage (to the device, the coupled optical fiber, or electrical connections between the device and the circuit board) that could be caused by that mounting. It may be desirable to arrange the mounting of the fiber-coupled optoelectronic device so as to reduce degradation of the device's frequency response due to spatially or temporally varying dielectric environment of its electrical connections. Disclosed herein are various embodiments of such circuit-mounted fiber-coupled optoelectronic devices, and methods of fabrication and use thereof, that can provide one or more of those desirable improvements.

### SUMMARY

An optoelectronic apparatus comprises: an optical fiber; an optoelectronic device; a device substrate; and a circuit board. The optoelectronic device is mounted on a top surface of a device substrate. The device substrate having a groove on the top surface for receiving the optical fiber and positioning a proximal end of the optical fiber to establish optical coupling between the optical fiber and the optoelectronic device. A first segment at or near the proximal end of the optical fiber is secured to the device substrate in the groove. The device substrate is mounted with its bottom surface on a top surface of the circuit board, and a second segment of the optical fiber (distal to the first fiber segment) is secured to the circuit board. One or more electrical connections are established between the optoelectronic device and one or more corresponding electrical contacts on the top surface of the circuit board. One or more vias formed in or through the circuit board provide electrical connections between corresponding electrical contacts on top and bottom surfaces of the circuit board.

A method for making the optical apparatus comprises: mounting on the circuit board the device substrate with the optoelectronic device; establishing the at least one electrical connection; securing the first fiber segment to the device substrate in the groove to establish the optical coupling; and securing the second fiber segment to the circuit board. Multiple device substrates can be secured to a single piece of circuit board material, which can be divided into individual circuit boards after establishing electrical connections and after securing optical fibers to the corresponding device substrates and to the circuit board material. Multiple fiber-coupled, board-mounted optoelectronic devices can be secured to a single system circuit board to form a multi-channel optoelectronic device array.

Objects and advantages pertaining to circuit-board-mounted, fiber-coupled optoelectronic devices or arrays thereof may become apparent upon referring to the exemplary embodiments illustrated in the drawings and disclosed in the following written description or claims.

### BRIEF DESCRIPTION OF THE DRAWINGS

FIG. 1 is a perspective view of an exemplary embodiment of a fiber-coupled optoelectronic device mounted on a circuit board.

FIG. 2 is a plan view of an exemplary embodiment of a fiber-coupled optoelectronic device mounted on a circuit board.

FIG. 3 is a side elevation view of an exemplary embodiment of a housing for a fiber-coupled optoelectronic device mounted on a circuit board.

FIGS. 4A-4C are schematic cross sectional views of an optical fiber secured to a circuit board.

FIG. 5 is a perspective view of an exemplary embodiment of a fiber-coupled optoelectronic device mounted on a circuit board.

FIG. 6 is a perspective view of an exemplary embodiment of a fiber-coupled optoelectronic device mounted on a circuit board.

FIG. 7 is a plan view of an exemplary embodiment of a fiber-coupled optoelectronic device mounted on a circuit board.

FIG. 8 is a side elevation view of an exemplary embodiment of a fiber-coupled optoelectronic device mounted on a circuit board.

FIG. 9 is a perspective view of an exemplary embodiment of a fiber-coupled optoelectronic device mounted on a circuit board, and a receptacle housing therefor.

FIG. 10 illustrates schematically a process for mounting fiber-coupled optoelectronic devices on circuit boards.

FIG. 11 illustrates schematically a process for mounting fiber-coupled optoelectronic devices on circuit boards.

FIG. 12 is a perspective view of an exemplary embodiment of a fiber-coupled optoelectronic device mounted on a circuit board.

FIG. 13 is a plan view of an exemplary embodiment of a fiber-coupled optoelectronic device mounted on a circuit board.

FIG. 14 is a bottom view of an exemplary embodiment of a housing for a fiber-coupled optoelectronic device mounted on a circuit board.

FIG. 15 is a perspective view of an exemplary embodiment of a fiber-coupled optoelectronic device mounted on a circuit board.

FIG. 16 is a plan view of an exemplary embodiment of a fiber-coupled optoelectronic device mounted on a circuit board.

FIG. 17 is a bottom view of an exemplary embodiment of a fiber-coupled optoelectronic device mounted on a circuit board.

FIG. 18A is a side cross-sectional view of an exemplary circuit board. FIG. 18B is a side cross-sectional view of an exemplary circuit board mounted on a system circuit board.

FIG. 19 is a plan view of multiple exemplary circuit-board-mounted, fiber-coupled optoelectronic devices mounted on a system circuit board.

FIG. 20 is a plan view of multiple exemplary circuit-board-mounted, fiber-coupled optoelectronic devices mounted on a system circuit board.

FIGS. 21A and 21B are plan views of an exemplary socket on a system circuit board and an exemplary circuit-board-mounted optoelectronic device mounted in the socket, respectively.

FIG. 22 illustrates schematically heating of a bottom surface of a system circuit board to effect solder reflow to secure an exemplary circuit-board-mounted optoelectronic device to the top surface of the system circuit board.

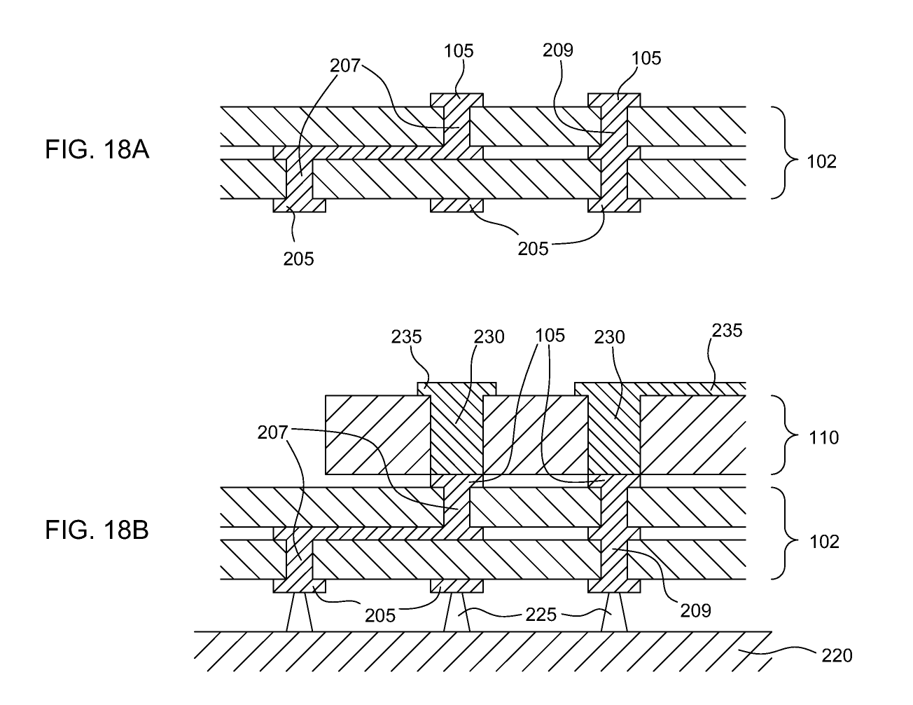

The embodiments shown in the Figures are exemplary, and should not be construed as limiting the scope of the present disclosure or appended claims. Relative sizes, shapes, or proportions shown in the drawings may be exaggerated for clarity and should not be regarded as limiting the scope of the present disclosure or appended claims. Various solder or adhesive layers have been omitted from some of the Figures for clarity (e.g., FIGS. 18A and 18B).

### DETAILED DESCRIPTION OF EMBODIMENTS

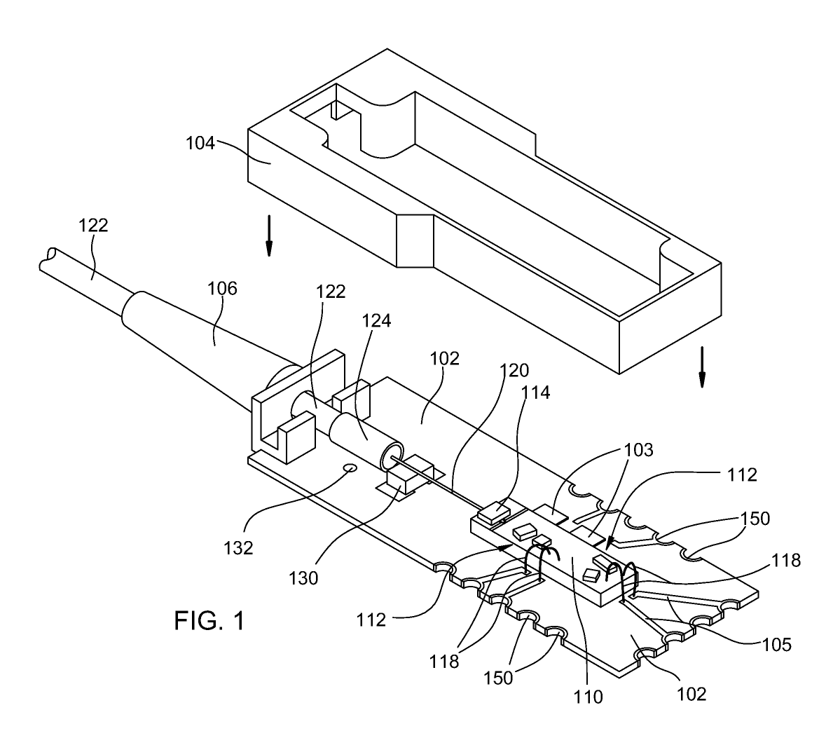

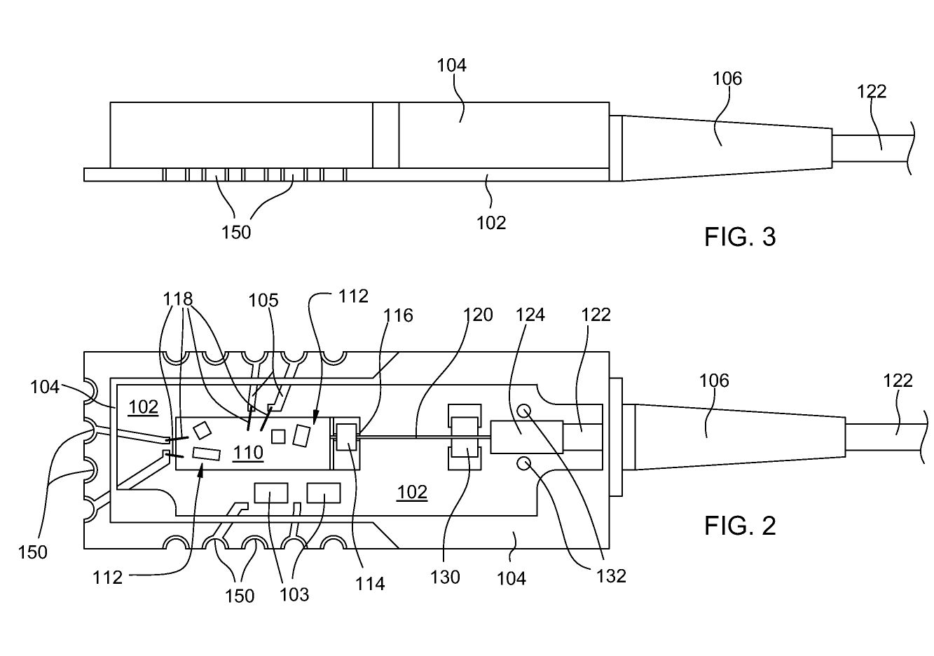

An optical apparatus is shown in FIGS. 1-3, and comprises: an optical fiber 120; one or more optoelectronic devices 112 on a device substrate 110; a circuit board 102; and at least one electrical connection 118 between optoelectronic device 112 and circuit board 102. Optoelectronic device 112 may comprise any desired optical component or device or set of optical components or devices, and may include (but is not limited to) one or more of the following: lasers or other optical sources, optical modulators, optical amplifiers, photodetectors or other optical receivers, other active optoelectronic components or devices, optical waveguides, optical couplers, reflectors, lenses, gratings, isolators, filters, other passive optical components, or other desired optical component(s). Electrical connection 118 may comprise one or more wire bonds between (a) a trace or contact 105 on circuit board 102 or an electronic component 103 on circuit board 102, and (b) device 112 or a trace or contact on device substrate 110 coupled to optoelectronic device 112. Alternatively, vias 230 can be formed through device substrate 110 to establish electrical connections between traces or contacts 235 on device substrate 110 and electrical contacts 105 on circuit board 102 (for example as shown FIG. 18B). Vias 230 can be metal filled or metal coated, or in some instances (e.g., for transmission of RF signals) can be filled or coated with a dielectric material of suitable frequency dependent permittivity. Any other suitable type or configuration may be employed for electrical connection 118.

Device substrate 110 has a groove 116 for receiving and positioning a proximal end of optical fiber 120 to establish optical coupling between the proximal end of optical fiber 120 and optoelectronic device 112. A first fiber segment at or near the proximal end of optical fiber 120 is secured to device substrate 110 in groove 116 (which is mostly obscured in the drawings). “Near” the proximal end of optical fiber 120 means that the proximal end of optical fiber 120 might extend beyond groove 116, but not far enough to permit movement of the proximal fiber end sufficient to substantially affect optical coupling between optical fiber 120 and optoelectronic device 112.

The proximal segment of the optical fiber 120 can be secured to the device substrate 110 in the groove 116 in any suitable way. For example, the apparatus can further comprise a fiber retainer 114 positioned over at least a portion of groove 116 and secured to device substrate 110 to secure the first segment of optical fiber 120 to device substrate 110 in groove 116. Adhesive (obscured in the drawings) may be employed for securing fiber retainer 114 to device substrate 110 as described in U.S. Pat. Pub. No. 2006/0002664 A1 (now U.S. Pat. No. 7,223,025) and U.S. Pat. Pub. No. 2007/0223864 A1 (now U.S. Pat. No. 7,625,132), each of said publications and patents being hereby incorporated by reference as if fully set forth herein. Any of the arrangements or adaptations disclosed therein for a fiber retainer may be employed while remaining within the scope of the present disclosure or appended claims. The adhesive may comprise a hardened material that had flowed into place during at least a portion of its application, and may comprise cured polymer, reflowed polymer, reflowed solder, reflowed glass, fused glass frit, or other similarly suitable adhesive or adhesive means (such as a cured epoxy resin, for example). Other suitable adhesives or adhesive means may be employed as well, including adhesives that do not flow during application.

In another example, other bonding methods can be employed to provide adhesion to secure the proximal segment of the optical fiber 120 to the device substrate 110 in the grove 116. So-called compression bonding of aluminum to silica or silicon is disclosed in U.S. Pat. Nos. 5,178,319 (Coucoulas) and 5,389,193 (Coucoulas et al), both of which are hereby incorporated by reference. The disclosed compression bonding methods can be employed, e.g., to bond an optical fiber (silica) into a groove 116 coated with aluminum, with adhesion of the aluminum coating to the silica fiber acting as an adhesive. Other bonding methods can be employed.

Device substrate 110 is mounted on circuit board 102, and a second segment of optical fiber 120 (distal to the first fiber segment) is secured to circuit board 102. The second fiber segment may be secured directly to circuit board 102, or may pass through a fiber buffer 122 that is in turn secured to circuit board 102. Buffer 122 may typically comprise one or more of polyvinyl chloride (PVC), Hytrel®, nylon, Kevlar®, or other suitable material, and any suitable buffer material or combination of buffer materials shall fall within the scope of the present disclosure or appended claims. Buffer 122 shall preferably comprise material(s) compatible with subsequent assembly, processing, or curing steps disclosed hereinbelow.

As shown in FIG. 1, device substrate 110 can be secured to a substantially flat region of circuit board 102. Likewise, buffer 122 (and hence the second segment of fiber 120) can be secured to a substantially flat region of circuit board 102. Those two substantially flat regions of circuit board 102 can be substantially coplanar. Such arrangement of device substrate 110, buffer 122, and optical fiber 120 results in at least a portion of the fiber 120 being vertically spaced-apart from the regions of the circuit board 102 to which the device substrate 110 and buffer 122 are secured.

It should be noted that in any of the embodiments disclosed herein, multiple grooves can be formed on a single device substrate for receiving multiple optical fibers. The multiple optical fibers are optically coupled to one or more optoelectronic devices on the device substrate, and the device substrate is mounted on a circuit board. The multiple optical fibers can be secured to the device substrate and to the circuit board as described in any of the embodiments disclosed herein.

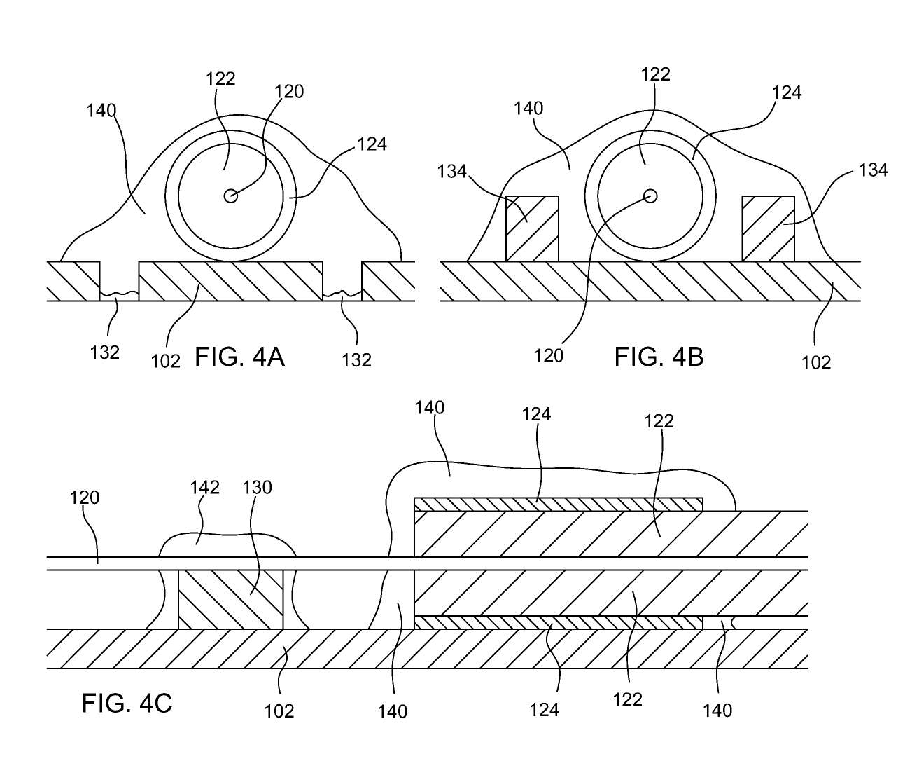

The optical apparatus may further comprise adhesive 140 for securing the second fiber segment (directly or via buffer 122) to circuit board 102 (FIGS. 4A-4C). Adhesive 140 may typically comprise a hardened material that had flowed into place during at least a portion of its application. For example (as described above), adhesive 140 may comprise cured polymer, reflowed polymer, reflowed solder, reflowed glass, fused glass frit, or other similarly suitable material. One example of a suitable cured polymer is a cured epoxy resin; other suitable adhesives or adhesive means may be employed as well, including adhesives that do not flow during application. If desired, crimp tube 124 can be crimped onto buffer 122 and secured to circuit board 102 by adhesive 140 (FIGS. 4A-4C), thereby securing buffer 122 to circuit board 102. The presence of crimp tube 124 has been observed to result in a more secure attachment of buffer 122 to circuit board 102 by adhesive 140. Adhesive 140 can cover at least a portion of crimp tube 122 and a portion of buffer 122 beyond one or both ends of crimp tube 124.

Instead of employing adhesives described above to secure the second fiber segment to the circuit board (directly or indirectly), compression bonding methods disclosed in U.S. Pat. Nos. 5,178,319 and 5,389,193 (described above) can be employed to act as the adhesive.

To further secure the attachment of buffer 122 (or direct attachment of the second segment of optical fiber 120) to circuit board 102, the apparatus may further comprise depressions 132 in or protrusions 134 on circuit board 102 (FIGS. 4A and 4B, respectively). Depressions 132 or protrusions 134 are positioned near the secured segment of buffer 122 and are at least partly covered by adhesive 140. Depressions 132 may comprise vias through circuit board 102 that are at least partly filled with adhesive 140. Depressions 132 are shown in the drawings laterally displaced from the secured portion of buffer 122, however, those locations are exemplary. Depressions 132 can be arranged laterally displaced from buffer 122, directly below buffer 122, or in any other suitable position for enhancing adhesion of buffer 122 (or optical fiber 120 or crimp tube 124) to circuit board 102. Protrusions 134 may comprise a member formed on or secured to circuit board 102 in any suitable way and at least partly covered by adhesive 140. Any suitable arrangement of protrusions 134 may be employed for enhancing adhesion of buffer 122 (or optical fiber 120 or crimp tube 124) to circuit board 102. Such a secured member can comprise an electrical component mounted on circuit board 102, which may be secured to circuit board 102 by solder or adhesive (such as epoxy resin, for example), and can also serve as a portion of an electronic circuit on circuit board 102.

The apparatus may further comprise a fiber support member 130 on circuit board 102 beneath a portion of optical fiber 120 between the first (i.e., proximal) fiber segment secured to device substrate 110 and the second fiber segment secured to circuit board 102 (directly or via buffer 122 or via crimp tube 124). At least a portion of optical fiber 120 is secured to fiber support member 130. Adhesive 142 may be employed for securing at least a portion of optical fiber 120 to fiber support member 130 (FIG. 4C). As described hereinabove, adhesive 142 may comprise a hardened material that had flowed into place during at least a portion of its application, and may comprise cured polymer, reflowed polymer, reflowed solder, reflowed glass, fused glass frit, or other similarly suitable adhesive or adhesive means. One example of a suitable material is a cured epoxy resin; other suitable adhesives or adhesive means may be employed as well, including adhesives that do not flow during application. Fiber support member 130 may comprise a member formed on or secured to circuit board 102 in any suitable way and at least partly covered by adhesive 142. Fiber support member 130 can comprise an electrical component mounted on circuit board 102, which may be secured to circuit board 102 by solder or adhesive (such as epoxy resin, for example), and can also serve as a portion of an electronic circuit on circuit board 102. Adhesives 140 and 142 may comprise discrete volumes of material (as in FIG. 4C), or may together comprise a single volume of material at least partly covering the secured portion of buffer 122 (or fiber 120 or crimp tube 124) as well as the portion of optical fiber 120 secured to fiber support member 130.

If needed or desired, the optical apparatus can further comprise an index-matching material between optoelectronic device 112 and the end of the optical fiber. Such an index-matching material can flow into place during application and then cure or harden, or can be placed between optoelectronic device 112 and the end of the optical fiber by any other suitable means. One example of a suitable material is an index-matching silicone polymer; any other suitable material can be employed.

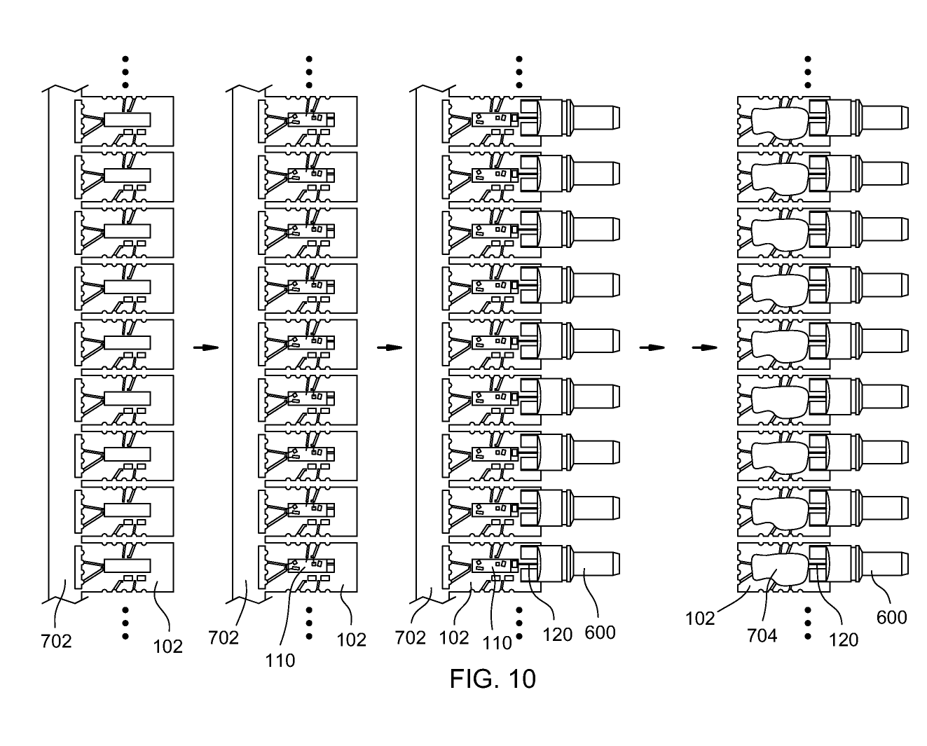

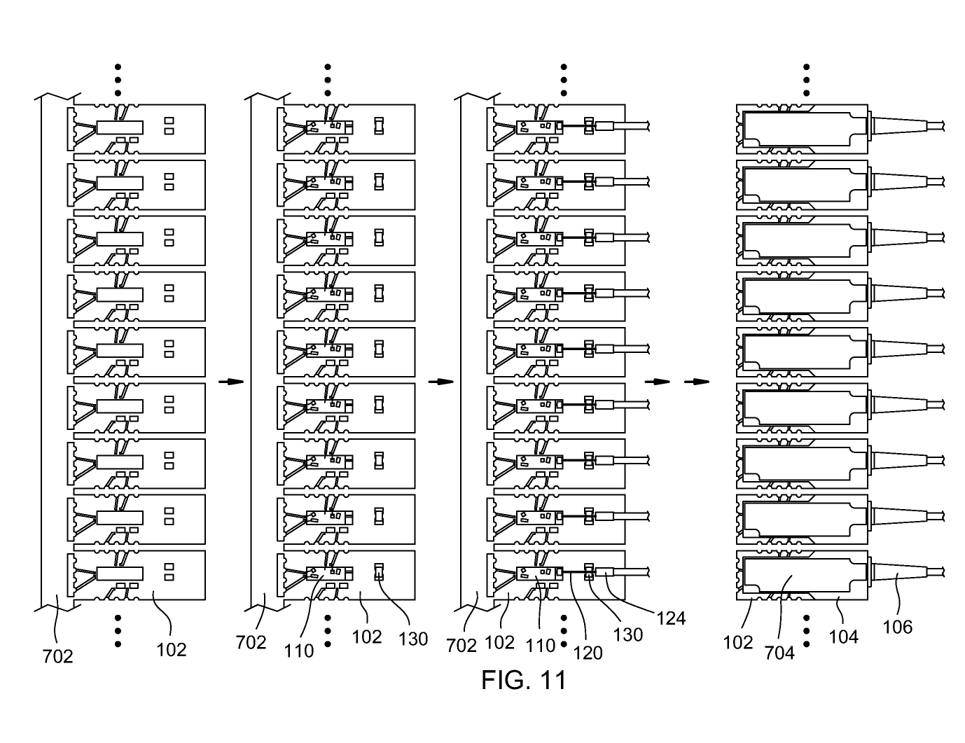

If needed or desired, the optical apparatus can further comprise an encapsulant 704, which can serve to protect the apparatus from a use environment. Any suitable encapsulant material can be employed, e.g., a silicone elastomer, and can be chosen based on any desired properties, e.g., rigidity or resilience, optical or dielectric properties, or thermal expansion coefficient. The encapsulant can substantially cover all or only some of the optoelectronic device 112, the device substrate 110, the proximal segment of the optical fiber 120, electrical connections 118, or a portion of the circuit board 102. In the examples shown in FIGS. 10 and 11, the encapsulant 704 covers all of those structures. In other examples, the encapsulant can be absent from various of those structures, e.g., the optical fiber 120 or the circuit board 102. In other examples, it may be desirable to limit the thickness or volume of the encapsulant 704 in order to reduce effects of thermal expansion mismatch between the encapsulant material and other materials of the optical apparatus, particularly if solder reflow is employed for establishing one or more electrical connections to the encapsulated optical apparatus.

If needed or desired, the apparatus can further comprise a housing 104 secured to circuit board 102 and having walls that substantially surround an area of circuit board 102 containing optoelectronic device 112, device substrate 110, and proximal segment 120 of the optical fiber, and can further comprise a lid substantially covering the surrounded area. An encapsulant (if employed) can substantially cover all or only some of the area of circuit board 102 surrounded by housing 104. If needed or desired, a strain-relief or bend-limiting structure 106 can be attached to housing 104 or circuit board 102 to restrict bending of the optical fiber near circuit board 102.

As shown in the drawings, circuit board 102 is made as small as practicable, and is suitable for in turn being mounted on a larger system circuit board as one of a plurality of components or subassemblies thereon. Such a so-called “boardlet” configuration enables ready integration of a fiber-coupled optoelectronic device (transmitter, receiver, bidirectional transceiver, and so on) into an electronic device, for enabling optical data transmission to or from the electronic device via the optical fiber. In such a configuration circuit board 102 may comprise any structure(s) or adaptation(s) suitable for enabling electrical connections between circuit board 102 and the system circuit board. For example, in FIGS. 1-3 electrical connections are established via contacts 150 formed on the edge of circuit board 102 and connected to traces or contacts 105. Alternatively, pins may be pre-inserted through circuit board 102 to protrude below circuit board 102 to mate with a suitably configured receptacle on the system circuit board.

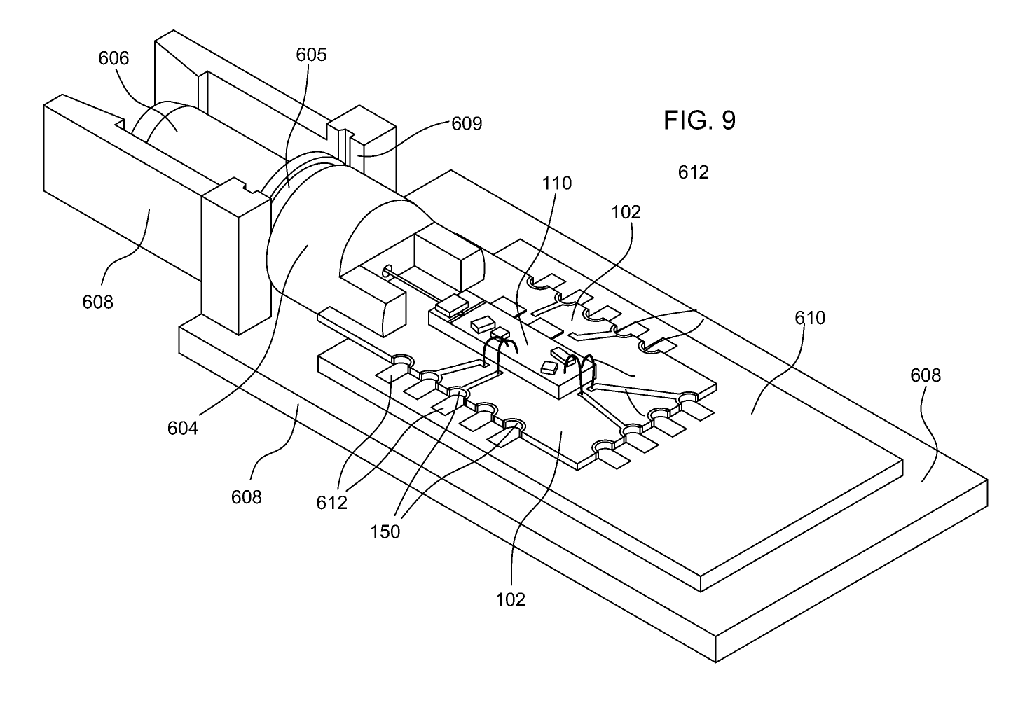

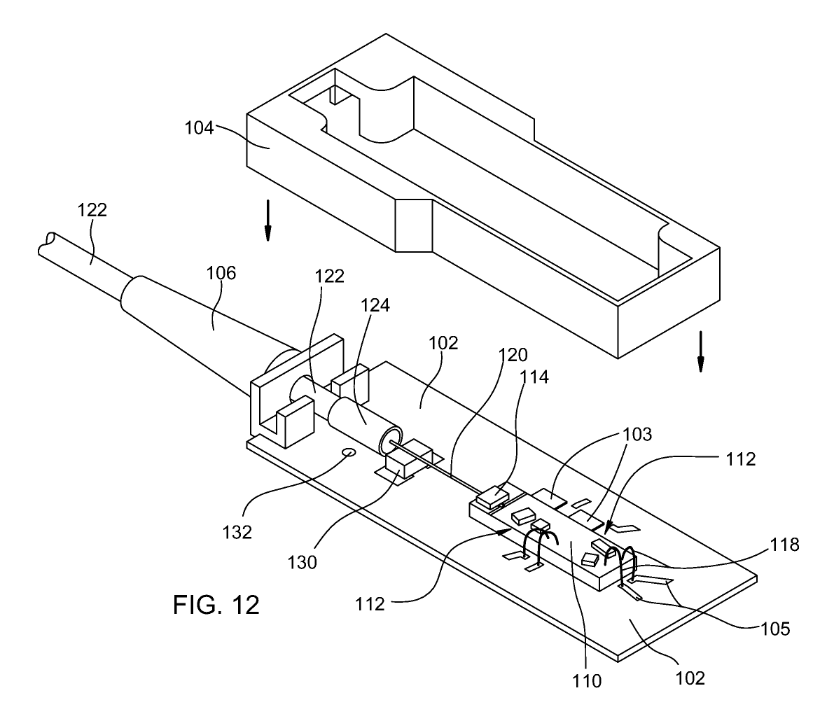

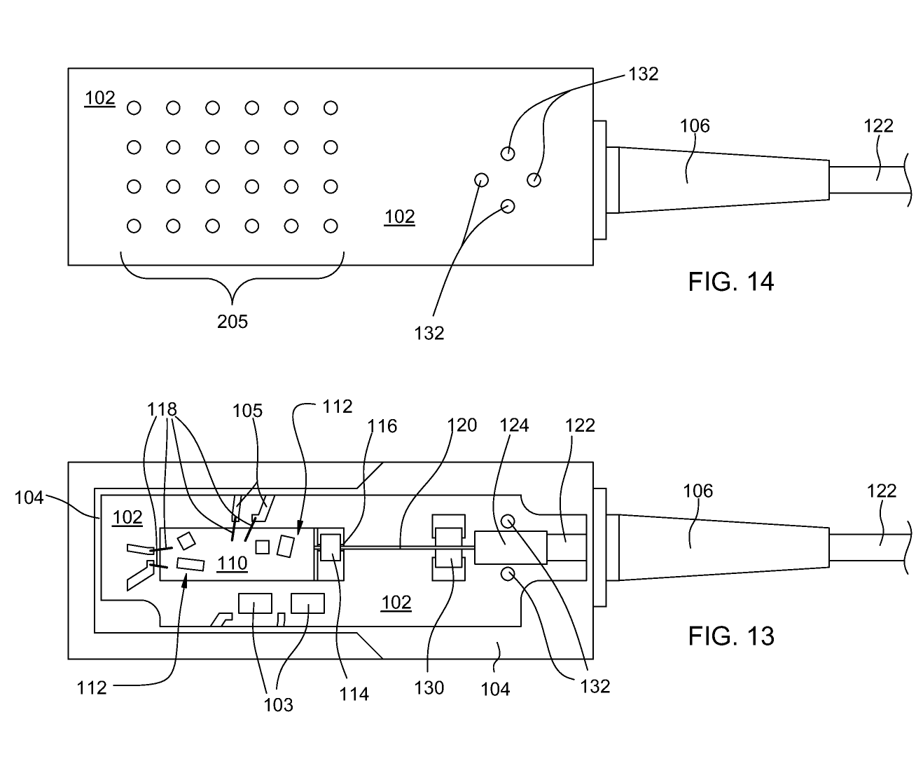

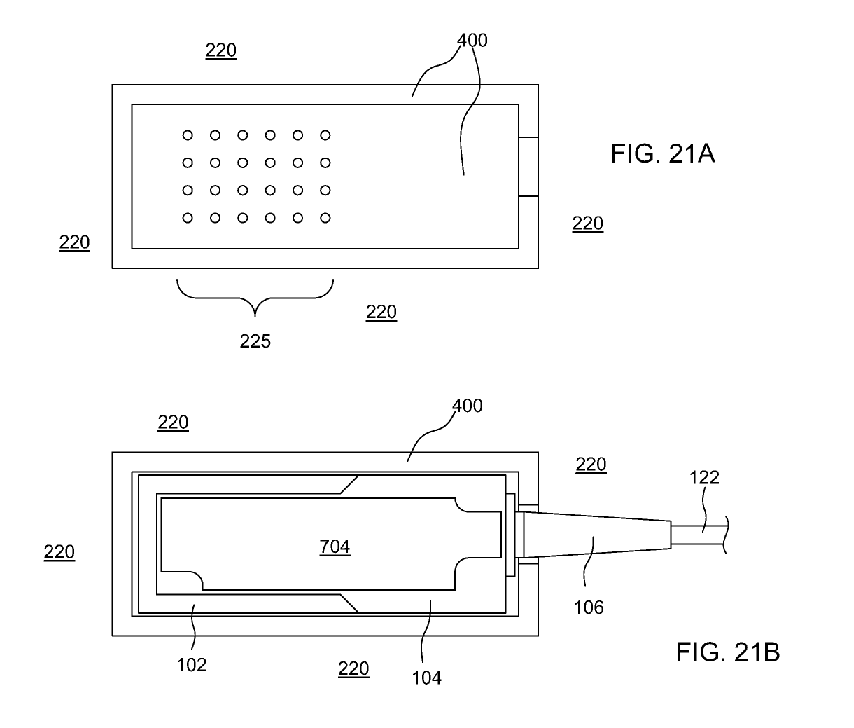

In another alternative arrangement (shown in FIGS. 12-14), a plurality of electrical contacts 205 can be provided on the bottom surface of circuit board 102. The electrical contacts 205 can be arranged or configured in any suitable way, including as a land grid array, a pin grid array, or a ball grid array. Although the contacts 205 are shown in the these and other figures arranged in a square grid pattern, any suitable regular or irregular array or pattern can be employed. A given circuit board 102 can include both types of electrical contacts, i.e., edge contacts 150 and bottom contacts 205. Mating pins 225, receptacles, or solder pads can be arranged on a system circuit board 220 so as to mate, when the circuit board 102 is mounted on the system circuit board 220, with one or more edge contacts 150 (as in the Example of FIG. 9) or with one or more bottom contacts 205 (as in the example of FIG. 18B). Alternatively, the system circuit board 220 can include a socket 400 for receiving circuit board 102 and establishing electrical connections with contacts 150 or 205 (e.g., as in FIGS. 21A and 21B). The embodiment of FIGS. 12-14 can be employed for achieving a high density of optoelectronic devices on a single system circuit board, as described further below.

Electrical connections can be established between electrical contacts 105 on the top surface of circuit board 102 and electrical contacts 205 on the bottom surface of circuit board 102 in any suitable way. One common way to achieve such connections is to employ a laminate structure for circuit board 102 that includes one or more intermediate conductive layers and metal-filled or metal plated vias in circuit board 102 (blind vias 207 or through vias 209; as shown in the example of FIG. 18A).

In some instances, not all contacts 105, 150, or 205 are employed to establish electrical connections. Those contacts not employed for an electrical connection can be employed as structural attachments, as alignment features, or for providing thermal conduction.

In any of the “boardlet” arrangements, mechanical alignment pins may be provided for positioning the “boardlet” on the system circuit board. Such alignment pins may be arranged for engaging mating holes on the system circuit board in any suitable way, and may be provided on circuit board 102 or provided on housing 104 extending through circuit board 102.

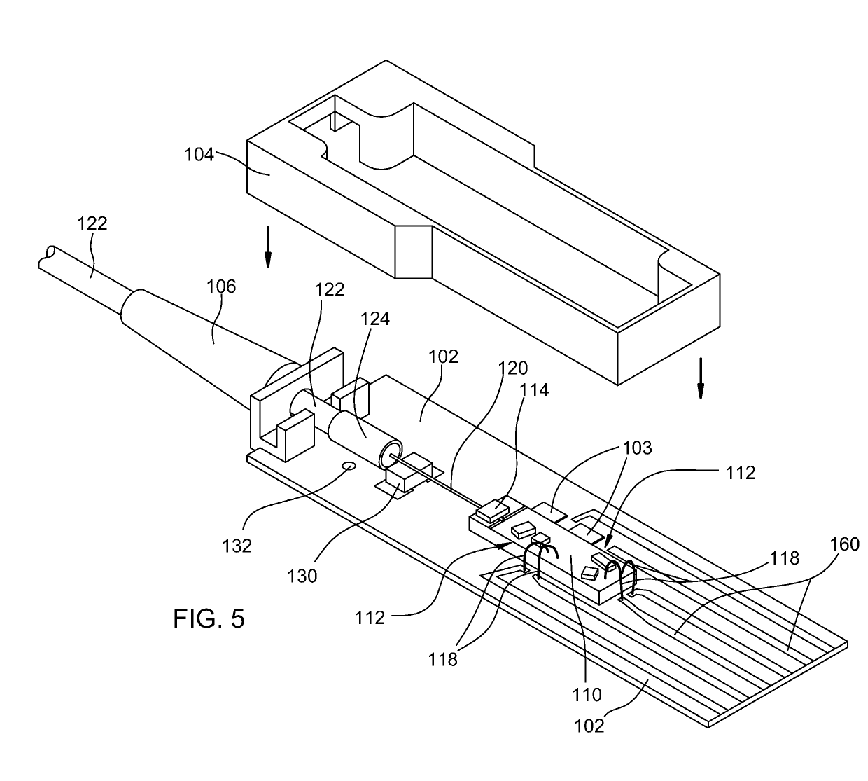

In another alternative embodiment (not shown), the optoelectronic device substrate 110 and optical fiber buffer 122 may be secured directly to the system circuit board (which would therefore be designated as circuit board 102) for integration into the electronic device. Such a configuration might be referred to as “chip-on-board”. In another alternative embodiment (FIG. 5), conductive traces 160 may extend to an edge of circuit board 102, which may in turn be inserted into a receptacle slot having mating conductive members. Such an arrangement may be suitable, for example, for incorporating the circuit board 102 (with optoelectronic device 110 thereon) into a so-called active fiber-optic cable.

A method for making the optical apparatus comprises: mounting on circuit board 102 device substrate 110 with one or more optoelectronic devices 112 and groove 116; establishing electrical connection(s) 118 between optoelectronic device 112 and circuit board 102; securing a first (proximal) segment of optical fiber 120 to device substrate 110 in groove 116; and securing a second segment of optical fiber 120 (distal to the first fiber segment) to circuit board 102. The second fiber segment may be secured directly to circuit board 102, or secured via a fiber buffer 122 or crimp tube 124. The method may further comprise applying adhesive 140 for securing buffer 122 or optical fiber 120 to circuit board 102, as variously described hereinabove. The method may further comprise positioning fiber support member 130 on circuit board 102 and securing at least a portion of optical fiber 120 to fiber support member 130, as variously described hereinabove, including application of adhesive 142. The method may further comprise securing fiber retainer 114 to device substrate 110 over at least a portion of groove 116 to secure the first fiber segment to device substrate 110 in groove 116, as variously described hereinabove, including application of adhesive. The method may further comprise substantially covering optoelectronic device 112, device substrate 110, and proximal segment 120 of the optical fiber with an encapsulant 704, or securing housing 104 to circuit board 102 substantially surrounding an area of circuit board 102 containing optoelectronic device 112, device substrate 110, and proximal segment 120 of the optical fiber.

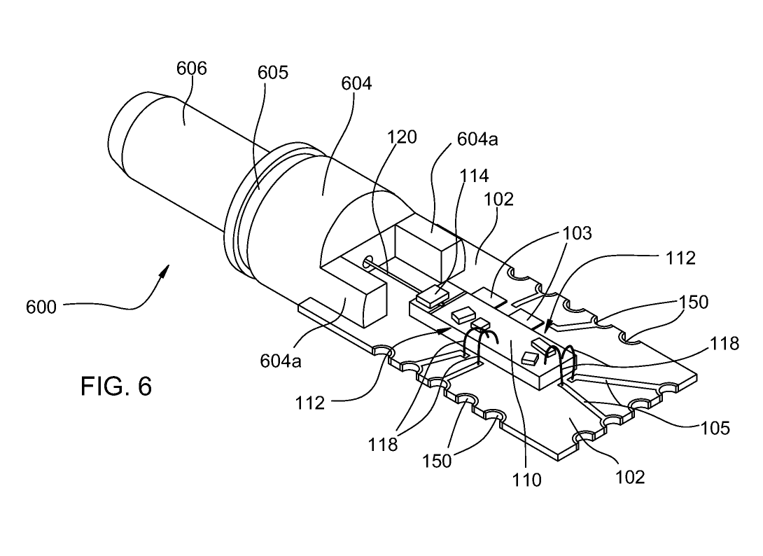

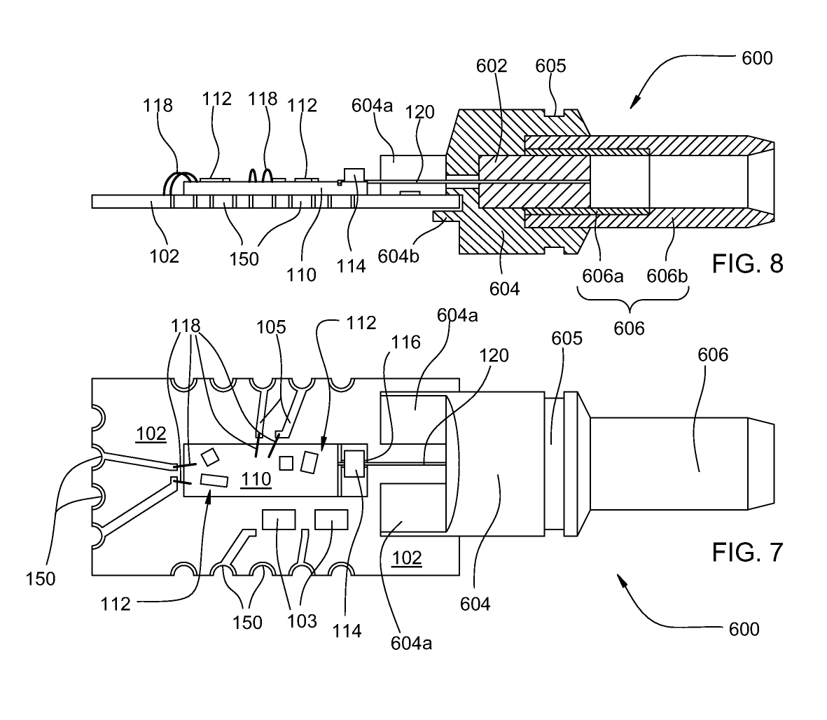

An alternative embodiment of a fiber-coupled optoelectronic device mounted on a circuit board is shown in FIGS. 6-9, in which the second segment of the optical fiber 120 is secured to a receptacle connector 600 which is in turn secured to circuit board 102. The receptacle connector 600 comprises a fiber ferrule 602, a ferrule holder 604, and a ferrule sleeve 606. The optical fiber 120 is secured to ferrule 602 with its distal end substantially flush with the distal end of ferrule 602, with its proximal end protruding from the proximal end of ferrule 602, and with its second segment within ferrule 602 (typically secured to the ferrule with epoxy or other suitable adhesive; any suitable means for securing the fiber to the ferrule can be employed). The optical fiber 120 in this embodiment is typically (though not necessarily) stripped of any buffer or outer coating; if initially present, a hermetic coating (e.g., a hermetic carbon coating) can be left in place, if needed or desired. Fiber ferrule 602 comprises ceramic or other suitable material(s). Ferrule holder 604 comprises plastic, metal, or other suitable material(s), and fiber ferrule 602 is secured to ferrule holder 604 in any suitable way, including press fit, adhesive, retainer(s), detent(s), welding, and so forth. When fiber ferrule 602 and ferrule holder 604 are assembled, the proximal end of optical fiber 120 protrudes from the proximal end of ferrule holder 604, while the distal ends of optical fiber 120 and fiber ferrule 602 are recessed within the ferrule holder 604. The ferrule holder 604 is secured by adhesive or other suitable means to the circuit board 102, thereby securing the second segment of the optical fiber 120 to the circuit board 102 (through fiber ferrule 602 and ferrule holder 604). The ferrule holder 604 is positioned on circuit board 102 so as to position the first segment of the optical fiber 120 in groove 116 on device substrate 110. The first segment of optical fiber 120 is secured to the device substrate 110 in groove 116 in any suitable way, including those described hereinabove. The device substrate 110 and the proximal end of optical fiber 120 can be encapsulated or enclosed in a housing, as described hereinabove.

As shown in FIGS. 6, 8, and 9, device substrate 110 can be secured to a substantially flat region of circuit board 102. Likewise, ferrule holder 604 (and hence the ferrule 602 and the second segment of fiber 120) can be secured to a substantially flat region of circuit board 102. Those two substantially flat regions of circuit board 102 can be substantially coplanar. The arrangement of device substrate 110, ferrule holder 604, ferrule 602, and optical fiber 120 results in at least a portion of the fiber 120 being vertically spaced-apart from the regions of the circuit board 102 to which the device substrate 110 and buffer 122 are secured.

In the example shown in FIGS. 6-9, ferrule holder 604 includes members 604a and 604b for engaging circuit board 102. Adhesive can be employed that flows into place during at least a portion of its application, including any of the examples disclosed herein; other suitable means can be employed as well. Grooves, depressions, vias, or protrusions on members 604a or 604b or on circuit board 102 may enhance the effectiveness of a flowing adhesive, by receiving some of the flowing material which then hardens to form a retaining member. Other suitable arrangements of ferrule holder 604 may be employed for enabling it to be secured to circuit board 102 using adhesive, solder, clamps, clips, pins, retainers, detents, welding (laser, ultrasonic, resistance, etc.), or other suitable means.

The ferrule sleeve 606 is arranged to receive another fiber ferrule of a mating connector (not shown) so as to align an optical fiber within the other fiber ferrule with the distal end of optical fiber 120 for optical end-coupling. To facilitate such alignment, ferrule sleeve may comprise an inner sleeve 606a and an outer sleeve 606b. The inner sleeve 606a can comprise a ceramic split sleeve, for example, arranged for ensuring substantially concentric alignment of fiber ferrule 602 and another fiber ferrule of a mating connector. The outer sleeve 606b can have a larger inner diameter than inner sleeve 606a, to more readily enable insertion of the other fiber ferrule into outer sleeve 606b and to guide the other fiber ferrule into inner sleeve 606a. Other suitable arrangements of sleeve 606 may be employed and shall fall within the scope of the present disclosure or appended claims.

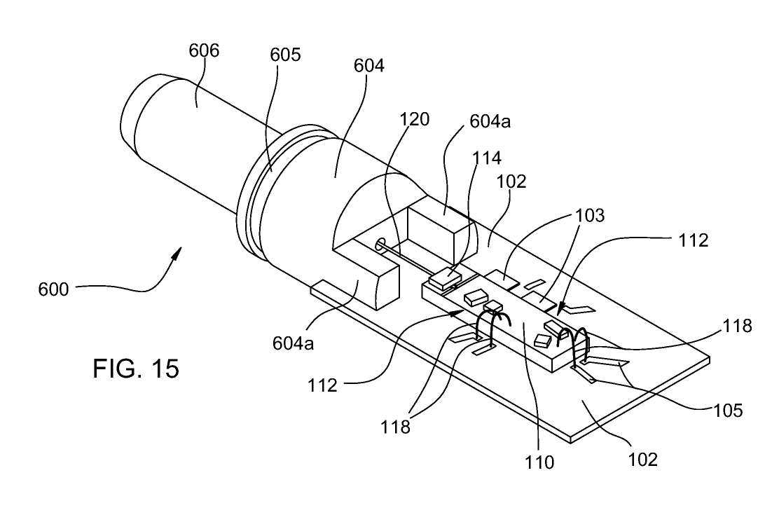

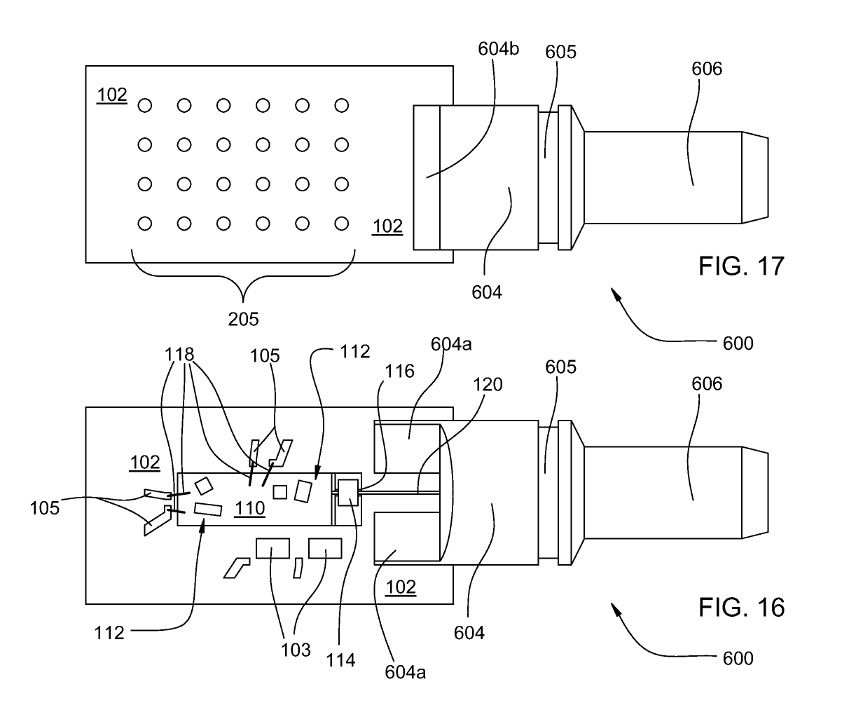

The ferrule holder 604 can be arranged or adapted on its outer surface for engaging or mating with a receptacle structure 608 (shown in FIG. 9). A circumferential groove 605 on the outer surface of ferrule holder 604 is shown in the exemplary embodiment of FIGS. 6-9, which receives an inwardly-projecting flange 609 of the receptacle structure 608. Any other suitable mechanical arrangement can be employed for engaging the ferrule holder 604 within the receptacle structure 608, and any such suitable arrangement shall be considered within the scope of the present disclosure or appended claims. The receptacle structure 608 typically is secured to a system circuit board 610. The receptacle structure 608 is positioned on the circuit board 610 so that engagement of the ferrule holder 604 with the receptacle structure 608 results in proper positioning of the circuit board 102 relative to the system circuit board 610 (within acceptable tolerances). Once the ferrule holder 604 is engaged with the receptacle structure 608, the circuit board 102 can be secured to the system circuit board 610 by solder, adhesive, or other suitable means. If soldered, the solder may also provide electrical connections between the circuit board 102 and the system circuit board 610 (as described hereinabove) utilizing contacts 150 (as in the example shown), conductive pins, or other suitable structures. In the example of FIG. 9, engagement of ferrule holder 604 with receptacle structure 608 (which is in turn secured to circuit board 610) results in alignment of contacts 150 on circuit board 102 with contacts 612 on circuit board 610. Alternatively, other electrical connections may be employed between circuit board 102 and system circuit board 600, such as wire bonds (not shown) or vias and bottom surface contacts 205 (FIGS. 15-17 and 18A-18B, as described above; that embodiment can be employed for achieving a high density of optoelectronic devices on a single system circuit board, as described further below.). Note that system circuit board 610 can extend beyond the receptacle structure 608 if needed or desired, and is shown smaller than the receptacle structure 608 in FIG. 9 in order to allow the relative positioning of the various parts of the overall assembly to be seen.

For any of the embodiments disclosed herein, multiple fiber-coupled optoelectronic devices can be mounted on a single contiguous piece of circuit board material, mounted directly on the system circuit board (i.e., “chip-on-board”) or mounted on a boardlet that is in turn mounted on the system circuit board. This may be done in order to construct a system circuit board having multiple fiber-coupled optoelectronic devices mounted thereon. Exemplary embodiments that include electrical contacts 205 on the bottom surface of circuit board 102 (e.g., the embodiments of FIGS. 12-14 and 15-17) can enable denser placement of multiple optoelectronic devices mounted on “boardlets” on a system circuit board (described further below), although boardlet embodiments with edge contacts, with both edge and bottom contacts, or with other suitable electrical connections to the system circuit board (e.g., wire bonds) also can be employed for a multiple-boardlet arrangement. Any suitable multiple-boardlet arrangement shall fall within the scope of the present disclosure or appended claims.

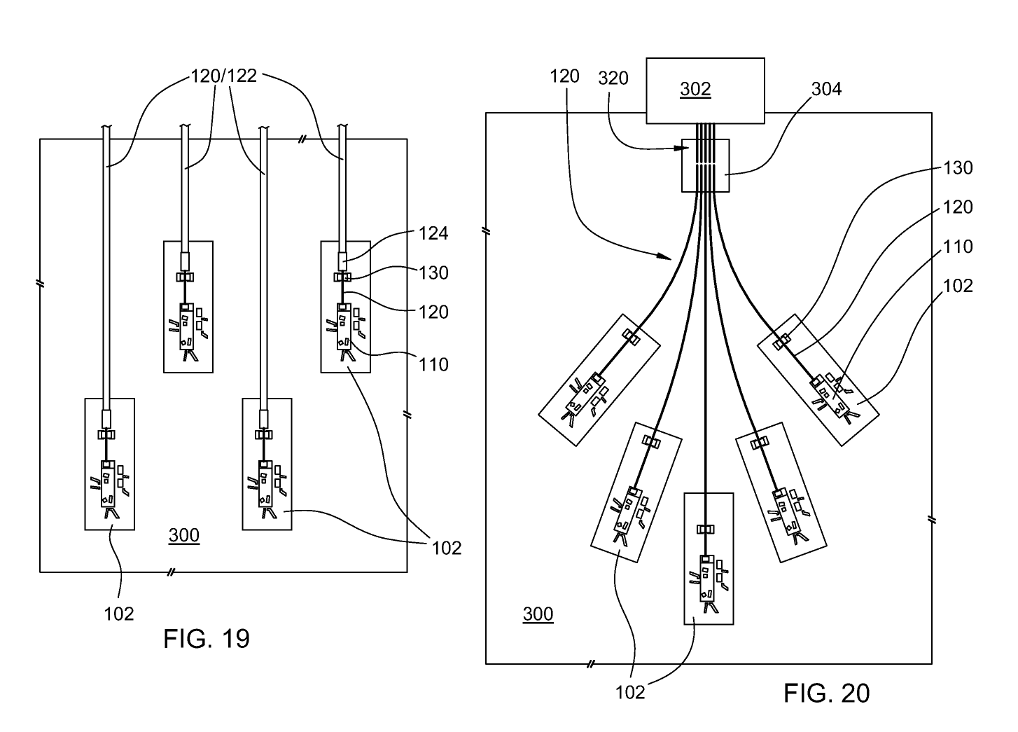

FIGS. 19 and 20 illustrate exemplary multiple-boardlet arrangements. The spatial arrangement (i.e., boardlet positions and orientations) shown in the Figures are exemplary only; any such arrangement can be employed, subject to mechanical or electrical constraints. Electrical connections between optoelectronic device and boardlet and between boardlet and system circuit board have been omitted for clarity, and can conform to any one or more of the arrangements disclosed herein. In the example of FIG. 19, multiple boardlets 102, each including a device substrate 110, fiber support 130, and crimp tube 124, are connected to system circuit board 300. Optical fibers 120 are secured to each device substrate 110, to each fiber support 130, and to each boardlet 102 with buffer 122 and crimp tube 124. In the example of FIG. 20, multiple boardlets 102, each including a device substrate 110 and fiber support 130, are connected to system circuit board 300. Optical fibers 120 are secured to each device substrate 110, to each fiber support 130, and to a fiber splice substrate 304 (e.g., a v-groove array). Optical fibers 320 are secured to the fiber splice substrate 304 and to a connector receptacle 302 of any suitable type or arrangement. The fiber splice substrate 304 aligns each optical fiber 120 and a corresponding optical fiber 320 for optical end-coupling. The end-coupled fibers can be fusion spliced or can have an index-matching medium deposited between them. The optical fibers 120 and 320 can be secured to the fiber splice substrate in an suitable way, including those disclosed herein (e.g., a fiber retainer, adhesive, and so on). A mating connector can engage receptacle connector 302 to optically couple the multiple boardlet devices to a cable comprising multiple optical fibers. The spliced arrangement of optical fibers 120 and 320 enables individual boardlet devices to be more readily removed and replaced from the system circuit board if found defective, instead of a more difficult removal of fiber 120 from connector receptacle 302 or scrapping the entire system circuit board and mounted boardlet devices. Nevertheless, embodiments wherein optical fibers 120 are connected directly to receptacle connector 302 shall fall within the scope of the present disclosure. If optical fibers 120 are connected directly to receptacle connector 302, fiber splice substrate 304 can be retained to act as a point of mechanical attachment of optical fibers 120 to system circuit board 300.

Fiber-coupled, boardlet-mounted, optoelectronic devices that employ electrical contacts 250 on the bottom surface of the boardlet 102 (e.g., as in FIGS. 12-14, 15-17, and 18A/18B) can be employed to produce a system circuit board having a high density of such devices. Bidirectional fiber-coupled devices (e.g., diplexers, triplexers, or other bidirectional optoelectronic transceivers) have become increasingly commonly deployed in telecommunications networks, and can be present in relatively large numbers in switching or headend facilities of telecommunications providers. A typical optoelectronic diplexer (one input channel and one output channel) generally requires at least four, and usually up to eight or nine or more, electrical connections for its operation; additional input or output channels (e.g., as in a triplexer) would require even larger numbers of electrical connections. The number of electrical connections needed can become a significant limitation on the number of bidirectional optoelectronic devices that can be mounted in a given amount of space on a common system circuit board.

The boardlet edge contacts 150 (e.g., as in FIGS. 1-3 and FIGS. 6-9) significantly limit the lineal density at which multiple boardlet-mounted devices can be mounted. Typically (and practically), a space on the order of at least a millimeter must be left between adjacent boardlets to enable electrical connections to be readily made between the edge contacts 150 and the system circuit board 220 (with the boardlets arranged in a single, non-staggered row). Closer spacing can cause connections of adjacent boardlets can interfere with one another, or hinder the assembly process. Placing all of the edge contacts 150 on the back edge of each boardlet (i.e., the edge opposite the coupled optical fiber) increases the width required for the boardlet itself, because the edge contacts 150 typically can be no closer than about one (1) millimeter apart (center-to-center) with standard manufacturing processes for printed circuit boards. For example, a boardlet-mounted device with 8 connections would need to be about 10 mm wide. However, bottom-surface contacts 250 (e.g., as in FIGS. 12-14 and 15-17) can be formed as close as about 1 mm apart or even about 0.5 mm apart (center-to-center) without substantial interference, and can be arrayed over the entire area of the bottom surface of a boardlet 102. In one example, a boardlet about 5 mm×10 mm can readily accommodate a 4×5 array of bottom-surface contacts 250 arranged on 1.27 mm centers (enabling a lineal density of up to about 2 devices per lineal centimeter). In another example, eight electrical connections required for a bidirectional optical device can be formed as a 2×4 array on 1.27 mm centers on a boardlet 102 of about 2.5 mm×7 mm (enabling a lineal density of up to about 4 devices per lineal centimeter), yielding a “Obit per linear inch” of electronic rack space (a relevant metric or figure-of-merit in the optoelectronic telecommunications industry) that is larger by about a factor of 4 than that possible using boardlets with only edge contacts 150. Boardlets even smaller (about 1 mm wide by about 3 mm long, enabling a lineal density of up to about 10 devices per lineal centimeter) can accommodate eight bottom-surface contacts 250 arranged in a 2×4 array about 0.5 mm apart, yielding another factor of about 2.5 of increased lineal device density. Because the fiber buffer of a typical optical fiber is about 0.9 mm in diameter, that boardlet size might be a practical lower limit for a single-fiber bidirectional device. Limitations on optoelectronic device density on a circuit board become more severe with additional input or output channels (e.g., as in a triplexer), which require additional electrical connections. Those additional connections can be more readily accommodated using a set of bottom surface contacts 250 than using edge contacts 150, and correspondingly higher device densities can be achieved.

A boardlet with bottom-surface contacts 250 typically is attached to a system circuit board by solder reflow. Such reflow is commonly achieved in the electronics industry by passing the components to be soldered in an oven that heats them beyond the solder reflow temperature; 240°-260° C. is a standard solder reflow temperature range. However, special care must be taken when attaching the boardlet mounted optoelectronic device to a system circuit board by reflow. The fiber buffer often cannot withstand such high temperatures (at limit of about 90° C. is common). Optical or mechanical encapsulants (described above) often exhibit thermal expansion coefficients that are an order of magnitude or more larger than the optoelectronic device, boardlet, or any housing that might be employed, therefore limiting the range of temperature excursions that can occur without damaging the encapsulated device, or requiring decreased thickness or volume of encapsulant to be used.

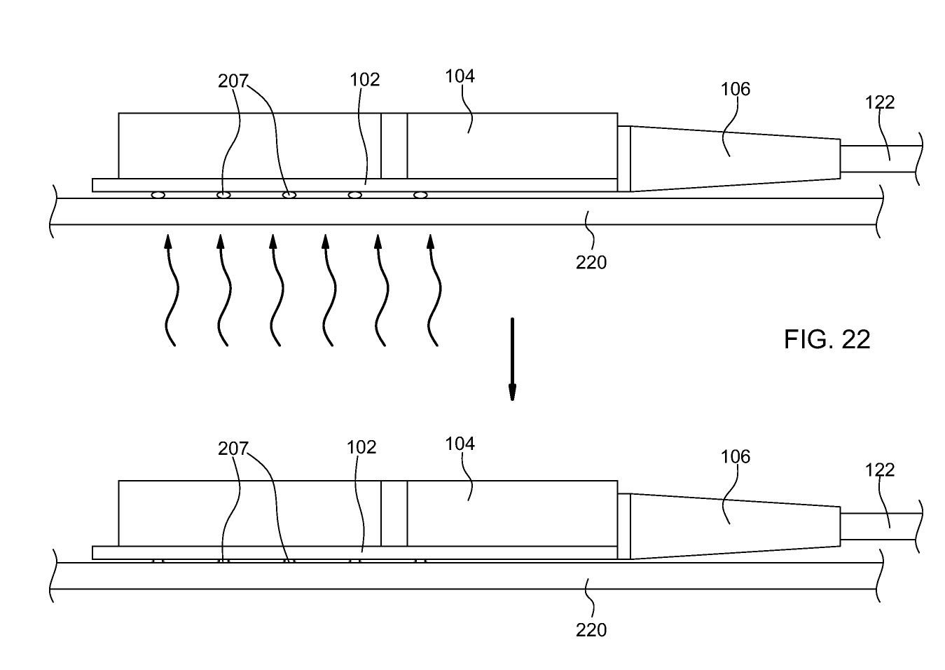

Some of those issues can be at least partly mitigated by employing heating to achieve solder reflow that is localized or of limited temporal duration. For example, a hot plate or radiative heater (not shown) can be employed to heat the system circuit board 220 from the bottom until solder 207 between the boardlet 102 and the top of the system circuit board 220 reflows and forms the desired connections (illustrated schematically in FIG. 22). The boardlet can serve to at least partly insulate the optoelectronic device, optical fiber, or encapsulant from the full brunt of the heating. Localized heat shielding can be interposed between the hot plate and the optical fiber. Rapid heating and cooling ramps (full temperature excursion in a few tens of seconds) can also be employed to reduce or limit the effects of elevated temperature on the fiber or encapsulant. A typical heating temporal profile might include a ramp from about 160° C. to about 260° C. in about 5 seconds, a dwell time of about 12 seconds at about 260° C., and cooling from about 260° C. to about 160° C. in about 5 seconds; other suitable heating temporal profiles can be employed. Alternatively, focused IR radiative heating systems can be employed for more accurately localized heating and solder reflow. In another alternative, soldering compounds can be employed that reflow at lower temperatures (e.g., less than about 150° C., or less than about 200° C.), reducing the likelihood that heating to the reflow temperature will damage the fiber or optoelectronic device.

The use of fiber-coupled, boardlet mounted, optoelectronic devices that have bottom-surface electrical contacts 250 can provide other advantages. Particularly at high speeds (e.g., RF or GHz frequencies), a spatially or temporally changing dielectric environment near any conductive leads or traces can alter the frequency response characteristics of the device. For a boardlet with edge contacts 150, electrical traces must traverse the boardlet surface beneath encapsulant, beneath a wall of a housing or enclosure, and is then an exposed portion of the surface near the boardlet edge. Those varying dielectric surroundings, and the possibility of intermittent contact on the exposed portions of the traces, can alter the frequency response of the device. In contrast, the conduction path through bottom-surface contacts 250 lead directly downward into a conductive layer of the system circuit board 220, which can be better shielded from variances in the dielectric environment.

A fiber-coupled, boardlet mounted, optoelectronic device with bottom-surface electrical contacts 250 can be employed wherein the device substrate and optical fiber are not necessarily arranged and secured to the boardlet as described elsewhere herein. The various disclosed advantages arising from use of such an arrangement of bottom-surface contacts on the boardlet can be realized regardless of the specific arrangement or attachment of the optoelectronic device or the optical fiber on the top surface of the boardlet, and such arrangements shall fall within the scope of the present disclosure or appended claims.

Multiple fiber-coupled devices can be mounted on a single piece of circuit board material to facilitate manufacture of multiple individual board-mounted devices. Examples of such multiple-board assembly processes are illustrated schematically in FIGS. 10 and 11. In each of these examples, multiple circuit boards 102 are all part of a single piece of circuit board material that includes a connecting strip 702. If needed or desired, the circuit board material can be scored, partially cut, or otherwise adapted to facilitate subsequent separation of the circuit boards 102 from the strip 702. While the multiple circuit boards remain attached to the strip 702, corresponding optoelectronic device substrates 110 (with optoelectronic devices assembled thereon) are secured to each circuit board 102, and any necessary electrical connections are made between the device substrates 110 and electrical traces or contacts 105 on the corresponding circuit board 102 (e.g., using wire bonds or vias through the device substrates 110).

With the multiple circuit boards 102 still attached to strip 702, corresponding optical fibers 120 are then assembled onto each circuit board 102. In FIG. 10, the optical fibers 120 are secured to the circuit boards with receptacle connectors 600 (as in FIGS. 6-9 and 15-17). After applying encapsulant 704, the circuit boards 102 are separated from the strip 702 to yield multiple individual “boardlet”-mounted, fiber-coupled optoelectronic devices. In FIG. 11, corresponding fibers 120 are secured to the circuit boards 102 with adhesive, support members 130, and crimp tube 124 (as in FIG. 1-3 or 12-14). After assembling housings 104, applying encapsulant 704, and assembling strain-relief structures 106, the circuit boards 102 are separated from the strip 702 to yield multiple individual “boardlet”-mounted, fiber-coupled optoelectronic devices. Any suitable method for securing fiber 120 to device substrate 110 and circuit board 102 may be employed in such a multiple-board assembly process, and all such suitable methods shall fall within the scope of the present disclosure or appended claims. Such multiple-board assembly procedures (as in the examples of FIGS. 10 and 11) enable significant economies to be realized in the manufacture of large numbers of boardlet-mounted, fiber-coupled optoelectronic devices.

It is intended that equivalents of the disclosed exemplary embodiments and methods shall fall within the scope of the present disclosure or appended claims. It is intended that the disclosed exemplary embodiments and methods, and equivalents thereof, may be modified while remaining within the scope of the present disclosure or appended claims.

In the foregoing Detailed Description, various features may be grouped together in several exemplary embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed exemplary embodiment. Thus, the appended claims are hereby incorporated into the Detailed Description, with each claim standing on its own as a separate disclosed embodiment. However, the present disclosure shall also be construed as implicitly disclosing any embodiment having any suitable combination of disclosed or claimed features (i.e., combinations of features that are not incompatible or mutually exclusive) that appear in the present disclosure or the appended claims, including those combinations of features that may not be explicitly disclosed herein. It should be further noted that the scope of the appended claims do not necessarily encompass the whole of the subject matter disclosed herein.

For purposes of the present disclosure and appended claims, the conjunction “or” is to be construed inclusively (e.g., “a dog or a cat” would be interpreted as “a dog, or a cat, or both”; e.g., “a dog, a cat, or a mouse” would be interpreted as “a dog, or a cat, or a mouse, or any two, or all three”), unless: (i) it is explicitly stated otherwise, e.g., by use of “either . . . or,” “only one of,” or similar language; or (ii) two or more of the listed alternatives are mutually exclusive within the particular context, in which case “or” would encompass only those combinations involving non-mutually-exclusive alternatives. For purposes of the present disclosure or appended claims, the words “comprising,” “including,” “having,” and variants thereof, wherever they appear, shall be construed as open ended terminology, with the same meaning as if the phrase “at least” were appended after each instance thereof.

In the appended claims, if the provisions of 35 USC §112 ¶ 6 are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC §112 ¶ 6 are not intended to be invoked for that claim.

What is claimed is:

1. An optoelectronic apparatus comprising:
an optical fiber;
an optoelectronic device on a top surface of a device substrate, the device substrate having a groove on the top surface for receiving the optical fiber and positioning a proximal end of the optical fiber to establish optical coupling between the optical fiber and the optoelectronic device, a first segment at or near the proximal end of the optical fiber being secured to the device substrate in the groove;
a circuit board, the device substrate being mounted with its bottom surface on a top surface of the circuit board, a second segment of the optical fiber being secured to the circuit board, the second fiber segment being distal to the first fiber segment;
one or more electrical connections between the optoelectronic device and one or more corresponding electrical contacts on the top surface of the circuit board; and
one or more vias formed in or through the circuit board to provide electrical connections between corresponding electrical contacts on top and bottom surfaces of the circuit board.

2. The apparatus of claim 1 wherein the electrical contacts on the bottom surface of the circuit board are arranged as a land grid array, a pin grid array, or a ball grid array.

3. The apparatus of claim 1 further comprising:
a system circuit board connected to and arranged to support the circuit board; and
one or more electrical connections, between the circuit board and the system circuit board, established through one or more of the electrical contacts on the bottom surface of the circuit board.

4. The apparatus of claim 3 wherein circuit board and the system circuit board are connected, and the electrical connections therebetween are established by, reflowed solder between the circuit board and the system circuit board, and the solder has a reflow temperature less than about 200° C.

5. The apparatus of claim 3 further comprising a socket on the system circuit board arranged to receive the circuit board and to establish the one or more electrical connections between the circuit board and the system circuit board.

6. The apparatus of claim 3 further comprising one or more additional fiber-coupled optoelectronic devices on corresponding additional device substrates, which additional device substrates are mounted on corresponding additional circuit boards that are supported by the system circuit board and connected to the system circuit board through one or more electrical contacts formed on the bottom surfaces of the additional circuit boards.

7. The apparatus of claim 6 wherein:
the optoelectronic devices comprise bidirectional devices and each includes eight or more electrical connections to corresponding electrical contacts on the bottom surface of the corresponding circuit board; and
the optoelectronic devices and the corresponding circuit boards are arranged on the system circuit board with a lineal density greater than about 2 devices per lineal centimeter.

8. The apparatus of claim 1 wherein at least one of the electrical connections between the optoelectronic device and the circuit board comprises a via formed through the device substrate that provides an electrical connection between the optoelectronic device and an electrical contact on a bottom surface of the device substrate.

9. The apparatus of claim 1 further comprising adhesive arranged so as to secure the second fiber segment to the circuit board.

10. The apparatus of claim 1 further comprising adhesive, or a fiber retainer positioned over at least a portion of the groove and secured to the device substrate, arranged so as to secure the first fiber segment to the device substrate in the groove.

11. The apparatus of claim 1 further comprising (i) an encapsulant substantially covering the optoelectronic device, the device substrate, and the first and second fiber segments, or (ii) a housing secured to the circuit board and having walls that substantially surround an area of the top surface of the circuit board containing the optoelectronic device, the device substrate, and the first and second fiber segments.

12. The apparatus of claim 1 further comprising:
a ferrule holder secured to the circuit board;
a fiber ferrule received within and secured to the ferrule holder and having the second fiber segment received therethrough and secured thereto, a distal end of the optical fiber being substantially flush with a distal end of the fiber ferrule, the fiber ferrule and ferrule holder thereby securing the second fiber segment to the circuit board; and
a ferrule sleeve received within and secured to the ferrule holder, the distal end of the fiber ferrule being received within a proximal end of the ferrule sleeve and recessed from a distal end of the ferrule sleeve, the distal end of the ferrule sleeve extending distally beyond a distal end of the ferrule holder.

13. A method for making an optical apparatus, the method comprising:
mounting on a circuit board a device substrate having on its top surface an optoelectronic device and a groove, the device substrate a being mounted with its bottom surface on a top surface of the circuit board, the circuit board including one or more vias formed in or through the circuit board to provide electrical connections between corresponding electrical contacts on top and bottom surfaces of the circuit board;
establishing one or more electrical connections between the optoelectronic device and one or more corresponding electrical contacts on the top surface of the circuit board;
securing a first segment at or near a proximal end of an optical fiber to the device substrate in the groove, the groove positioning the proximal end of the optical fiber to establish optical coupling between the optical fiber and the optoelectronic device; and
securing to the circuit board a second segment of the optical fiber, the second fiber segment being distal to the first fiber segment.

14. The method of claim 13 wherein the electrical contacts on the bottom surface of the circuit board are arranged as a land grid array, a pin grid array, or a ball grid array.

15. The method of claim 13 further comprising:
mounting the circuit board on a system circuit board; and
establishing, through one or more of the electrical contacts on the bottom surface of the circuit board, one or more electrical connections between the circuit board and the system circuit board.

16. The method of claim 15 wherein the system circuit board includes a socket arranged to receive the circuit board and to establish the one or more electrical connections between the circuit board and the system circuit board.

17. The method of claim 15 wherein mounting the circuit board on the system circuit board, and establishing electrical connections between the circuit board and the system circuit board, is achieved by reflow of solder between the circuit board and the system circuit board, and that reflow is achieved by localized heating of only a bottom surface of the system circuit board.

18. The method of claim 15 wherein mounting the circuit board on the system circuit board, and establishing electrical connections between the circuit board and the system circuit board, is achieved by reflow of solder between the circuit board and the system circuit board, and the solder has a reflow temperature less than about 200° C.

19. The method of claim 15 further comprising mounting one or more additional circuit boards on the system circuit board, which additional circuit boards have mounted thereon corresponding additional fiber-coupled optoelectronic devices on corresponding additional device substrates, which additional circuit boards are connected to the system circuit board through one or more electrical contacts formed on the bottom surfaces of the additional circuit boards.

20. The method of claim 19 wherein:
the optoelectronic devices comprise bidirectional devices and each includes eight or more electrical connections to corresponding electrical contacts on the bottom surface of the corresponding circuit board; and
the optoelectronic devices and the corresponding circuit boards are arranged on the system circuit board with a lineal density greater than about 2 devices per lineal centimeter.

21. The method of claim 13 wherein at least one of the electrical connections between the optoelectronic device and the circuit board comprises a via formed through the device substrate that provides an electrical connection between the optoelectronic device and an electrical contact on a bottom surface of the device substrate.

22. The method of claim 13 wherein securing the second fiber segment to the circuit board comprises adhering the second fiber segment to the circuit board.

23. The method of claim 13 wherein securing the first segment of the optical fiber to the device substrate in the groove comprises adhering the first fiber segment to the device substrate in the groove, or securing a fiber retainer to the device substrate over at least a portion of the groove to secure the first fiber segment to the device substrate in the groove.

24. The method of claim 13 further comprising (i) substantially covering the optoelectronic device, the device substrate, and the first and second fiber segments with an encapsulant, or (ii) securing a housing to the circuit board, the housing having walls that substantially surround an area of the circuit board containing the optoelectronic device, the device substrate, and the first and second fiber segments.

25. The method of claim 13 further comprising:
securing a ferrule holder to the circuit board;
securing the second fiber segment within a fiber ferrule, a distal end of the optical fiber being substantially flush with a distal end of the fiber ferrule; and
securing a ferrule sleeve within the ferrule holder, the distal end of the fiber ferrule being received within a proximal end of the ferrule sleeve and recessed from a distal end of the ferrule sleeve, the fiber ferrule and ferrule holder thereby securing the second fiber segment to the circuit board.

26. A method for making a plurality of optical apparatus, comprising:
mounting on a top surface of circuit board material multiple device substrates each having thereon a corresponding optoelectronic device and a corresponding groove thereon, the circuit board material including a plurality of vias formed in or through the circuit board material to provide electrical connections between corresponding electrical contacts on top and bottom surfaces of the circuit board material;
establishing one or more electrical connections between each optoelectronic device and one or more corresponding electrical contacts on the top surface of the circuit board material;
securing a first segment at or near a proximal end of a corresponding optical fiber to each device substrate in the corresponding groove, the corresponding groove positioning the proximal end of the corresponding optical fiber to establish optical coupling between the corresponding optical fiber and the corresponding optoelectronic device;
securing to the circuit board material a second segment of each corresponding optical fiber, the second fiber segment being distal to the first fiber segment; and
dividing the circuit board material into individual circuit boards, each having a corresponding device substrate and optoelectronic device mounted thereon, a corresponding optical fiber secured thereto; and one or more corresponding electrical contacts on its bottom surface electrically connected to the corresponding optoelectronic device.
